(19) United States
(12) Patent Application Publication
(10) Pub. No.: US 2025/0044662 A1
(43) Pub. Date: Feb. 6, 2025

(54) Steerable projector of patterned illumination

(71) Applicant: APPLE INC., Cupertino, CA (US)

(72) Inventors: Julien Sarry, San Francisco, CA (US); April D. Schricker, Mountain View, CA (US)

(21) Appl. No.: 18/614,862

(22) Filed: Mar. 25, 2024

Related U.S. Application Data
(60) Provisional application No. 63/516,868, filed on Aug. 1, 2023.

(51) Int. Cl. G02F 1/29; G03B 21/00; G03B 21/20

(52) U.S. Cl. CPC G02F 1/292; G03B 21/006; G03B 21/206; G02F 2201/305; G02F 2202/30; G02F 2203/24

(57) ABSTRACT

Optoelectronic apparatus includes an array of emitters configured to emit respective beams of optical radiation. A steering module is mounted to intercept the emitted beams and includes an optical substrate and an active diffraction grating, which is fixed to the optical substrate and has a pitch that varies in response to an electrical signal applied thereto, so as to deflect the beams of optical radiation by a variable angle dependent on the pitch. An optical metasurface is disposed on the optical substrate and configured to collimate the beams of optical radiation so that the beams form a pattern of spots on a target scene. A controller is coupled to vary the electrical signal applied to the active diffractive grating so as to shift the pattern of spots across the target scene.

### CROSS-REFERENCE TO RELATED APPLICATION

This application claims the benefit of U.S. Provisional Patent Application 63/516,868, filed Aug. 1, 2023, which is incorporated herein by reference.

### FIELD

The present invention relates generally to optoelectronic devices, and particularly to sources of patterned optical radiation.

### BACKGROUND

Various sorts of portable electronic devices, such as smartphones, augmented reality (AR) devices, virtual reality (VR) devices, smart watches, and smart glasses, comprise compact sources of optical radiation. Such a source may, for example, project optical radiation to illuminate a target region with a pattern of spots for three-dimensional (3D) mapping of the region, also referred to as depth mapping.

In this regard, U.S. Pat. No. 10,305,247 describes an optical apparatus that includes an array of lasers, which are arranged in a grid pattern and emit respective beams of pulses of optical radiation. Projection optics project the beams toward a target with an angular pitch between the beams defined by the spatial pitch of the array and the focal length of the optics. A scanner scans the projected beams over a range of scan angles that is less than twice the angular pitch. A receiver receives and measures a time of flight of the pulses reflected from the target.

The terms “optical rays,” “optical radiation,” and “light,” as used in the present description and in the claims, refer generally to electromagnetic radiation in any or all of the visible, infrared, and ultraviolet spectral ranges.

Optical metasurfaces are thin layers that comprise a two-dimensional pattern of structures, having dimensions (pitch and thickness) less than the target wavelength of the radiation with which the metasurface is designed to interact. The dimensions and arrangement of the structures on the metasurface are designed to apply specific local modifications to the phase, amplitude, and/or polarization of incident radiation. Optical elements comprising optical metasurfaces are referred to herein as “metasurface optical elements” (MOEs).

### SUMMARY

Embodiments of the present invention that are described herein provide apparatus and methods for optical projection.

There is therefore provided, in accordance with an embodiment of the invention, optoelectronic apparatus, including array an of emitters configured to emit respective beams of optical radiation and a steering module, mounted to intercept the emitted beams. The steering module includes an optical substrate and an active diffraction grating, which is fixed to the optical substrate and has a pitch that varies in response to an electrical signal applied thereto, so as to deflect the beams of optical radiation by a variable angle dependent on the pitch. An optical metasurface is disposed on the optical substrate and configured to collimate the beams of optical radiation so that the beams form a pattern of spots on a target scene. A controller is coupled to vary the electrical signal applied to the active diffractive grating so as to shift the pattern of spots across the target scene.

In a disclosed embodiment, the emitters include vertical-cavity surface-emitting lasers (VCSELs).

In some embodiments, the active diffraction grating includes an electro-optical material, such as at least one liquid crystal. In one embodiment, the at least one liquid crystal includes a first liquid crystal, which is configured to deflect the beams of optical radiation along a first direction, and a second liquid crystal, which is configured to deflect the beams of optical radiation along a second direction, perpendicular to the first direction.

In some embodiments, the apparatus includes a receiver, which is configured to receive the optical radiation that is reflected from the pattern of spots on the target scene and to measure distances to points in the target scene responsively to the received optical radiation. In a disclosed embodiment, the receiver has a field of view having a first angular width, while the pattern of spots extends over a second angular width, which is less than half the first angular width. The controller may be configured to identify an area of interest within the field of view and to set the electrical signal so as to position the pattern of spots on the area of interest.

There is also provided, in accordance with an embodiment of the invention, a method for optical projection, which includes directing an array of beams of optical radiation to impinge on a steering module, which includes an active diffraction grating, which has a pitch that varies in response to an electrical signal applied thereto and is fixed to an optical substrate, and an optical metasurface disposed on the optical substrate and configured to collimate the beams of optical radiation so that the beams form a pattern of spots on a target scene. The electrical signal applied to the active diffractive grating is varied so as to deflect the beams of optical radiation by a variable angle dependent on the pitch, thereby shifting the pattern of spots across the target scene.

The present invention will be more fully understood from the following detailed description of the embodiments thereof, taken together with the drawings in which:

### BRIEF DESCRIPTION OF THE DRAWINGS

FIG. 1 is a schematic side view of an optoelectronic apparatus, in accordance with an embodiment of the invention;

FIG. 2 is a schematic sectional view of a projection module, in accordance with an embodiment of the invention;

FIG. 3A is a schematic sectional view of an active diffraction grating, in accordance with an embodiment of the invention;

FIG. 3B is an exploded view showing functional elements of the active diffraction grating of FIG. 3A; and

FIG. 4 is a schematic frontal view of a target scene, illustrating the operation of an active diffraction grating in steering a pattern of spots across the scene, in accordance with an embodiment of the invention.

### DETAILED DESCRIPTION

As noted above, some depth mapping systems project a pattern of spots onto a target scene that is to be mapped. In some of these systems, the pattern is created by a laser or an array of lasers, such as vertical-cavity surface-emitting lasers (VCSELs). This approach is advantageous in creating intense, well-defined spots, as well as in generating short pulses when needed for measuring times of flight. The spatial resolution of the pattern is limited by the number of spots that are projected onto the target scene, which may in turn be limited by optical and electrical power constraints.

Typically, semiconductor-based optical emitters, such as VCSELs, emit beams with large angles of divergence. To form a well-defined pattern on the target scene, a projection lens collimates the beams. When a refractive lens (typically a compound lens) is used for this purpose, and the pattern projector is to be incorporated into a portable electronic device, the total track length of the lens may be a limiting factor in reducing the overall thickness of the device.

Embodiments of the present invention that are described herein provide spot projectors that address both these problems: They project a dense, well-defined pattern of spots while maintaining a thin overall profile. These objects are achieved by using an optical metasurface to collimate the beams from an array of emitters and project a dense pattern of spots with a narrow angular divergence. To reach the desired pattern density with a limited number of emitters in the array, the angular width of the pattern projected by the optical metasurface may cover only a part of the target scene. To compensate for the narrow angular width of the pattern, an active diffraction grating steers this pattern of spots over the target scene, and thus projects the pattern onto a particular area of interest and/or sweeps the pattern sequentially over the entire scene. The optical metasurface can advantageously be formed on an optical substrate of the active diffraction grating, rather than as a separate element, so that the total track length of the optics is limited only by the thickness of the active diffraction grating itself. For example, the active diffraction grating may comprise a liquid crystal, with an optical metasurface formed on the transparent envelope of the liquid crystal.

Thus, the disclosed embodiments provide optoelectronic apparatus, comprising an array of emitters, such as VCSELs, which emit respective beams of optical radiation. A steering module is mounted to intercept the emitted beams. The steering module comprises an active diffraction grating, which is fixed to an optical substrate and has a pitch that varies in response to an electrical signal applied to the active diffraction grating. The active diffraction grating deflects the beams of optical radiation by a variable angle, which depends on the pitch. An optical metasurface, which is disposed on the optical substrate, collimates the beams of optical radiation to form a pattern of spots on a target scene. A controller varies the electrical signal applied to the active diffractive grating so as to shift the pattern of spots across the target scene.

Patterns of spots that are projected in this manner can be used in various applications, such as range measurement and 3D mapping. In some embodiments, the emitters output pulsed beams of optical radiation, and a receiver receives and measures the time of flight of the pulses reflected from the target scene, as in the above-mentioned U.S. Pat. No. 10,305,247. Alternatively, the emitters may output modulated CW beams, which may be used, for example, in frequency-modulated continuous-wave (FMCW) LIDAR. Alternative applications of the principles described herein will be apparent to those skilled in the art after reading the present disclosure and are considered to be within the scope of the present invention.

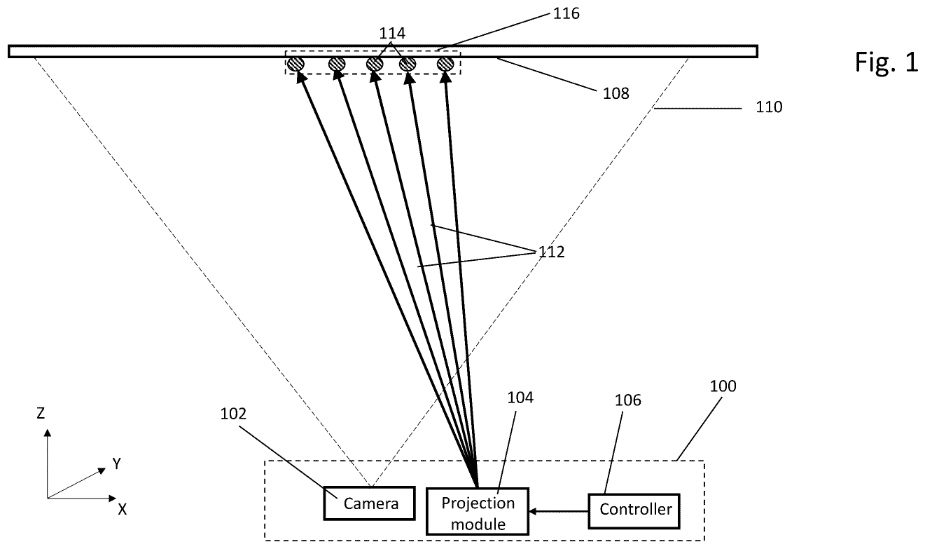

FIG. 1 is a schematic side view of an optoelectronic apparatus 100, in accordance with an embodiment of the invention. Optoelectronic apparatus 100 comprises a camera 102, a projection module 104, and a controller 106. Projection module 104 emits multiple beams 112 of optical radiation, illuminating an area 116 of a target scene 108 with a pattern of spots 114. In response to electrical signals output by controller 106, projection module 104 shifts the pattern across the target scene.

Camera 102 serves as a receiver, to receive the optical radiation that is reflected from the pattern of spots 114 on target scene 108. For example, camera 102 may capture an image of the scene and/or sense times of flight of the photons that are reflected from beams 112. Based on these images and/or times of flight, camera 102 measures distances to points in target scene 108. Camera 102 has a field of view 110 that is much wider than the area 116 that is illuminated by projection module 104 at any given time. For example, the angular width of area 116 may be less than half the angular width of field of view 110.

In one embodiment, controller 106 identifies an area of interest within field of view 110 and sets the electrical signal that it applies to projection module 104 so as to position the pattern of spots 114 on the area of interest. The area of interest may be identified interactively by a user of apparatus 100, for example, or it may be identified automatically, for example by processing an image captured by camera 102 to identify an object of interest within field of view 110. This latter mode of operation can be useful, inter alia, when distance measurement based on spots 114 is applied in precisely setting the autofocus of camera 102 or of another imager. The ability to select an area of interest and to position the pattern of spots 114 in the selected area can also be useful in other depth and range-sensing applications, for example room measurements, video conferencing, augmented reality, and navigation.

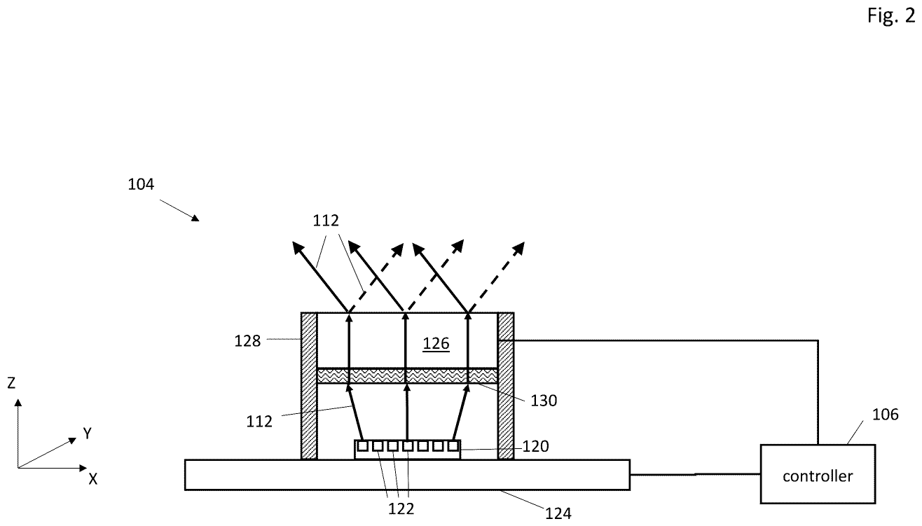

FIG. 2 is a schematic sectional view of projection module 104, in accordance with an embodiment of the invention. Projection module 104 comprises an array 120 of VCSELs 122, which is mounted on a substrate 124. For example, array 120 may comprise an integrated circuit chip containing the VCSELs and associated drive circuits, while substrate 124 comprises a printed circuit board. Each VCSEL emits a respective one of beams 112. Although only a small number of VCSELs and corresponding beams are shown in FIG. 2, in practice array 120 may comprise a much larger number of VCSELs, for example one hundred VCSELs or more.

In alternative embodiments, other types of emitters may be used, such as photonic crystal-cavity surface-emitting lasers (PCSELs) or vertical-external-cavity surface-emitting lasers (VECSELs). In some embodiments, such as in FMCW LIDAR, the emitters may be integrated with silicon photonic components.

A steering module 128 is mounted over array 120 and intercepts beams 112 that are emitted by VCSELs 122. Steering module 128 comprises an active diffraction grating 126, for example a tunable 3D grating based on a suitable electro-optical material, such as liquid crystals, as described further hereinbelow. An optical metasurface 130 is formed on an optical substrate of active diffraction grating 126. Metasurface 130 collimates and projects beams 112 so that the beams form a pattern of spots on a target scene, as shown in FIG. 1, obviating the need for a refractive lens in the projection module. Controller 106 applies a variable electrical signal to active diffraction grating 126 so as to change the angle of deflection of beams 112 by the active diffraction grating and thus shift the pattern of spots across the target scene.

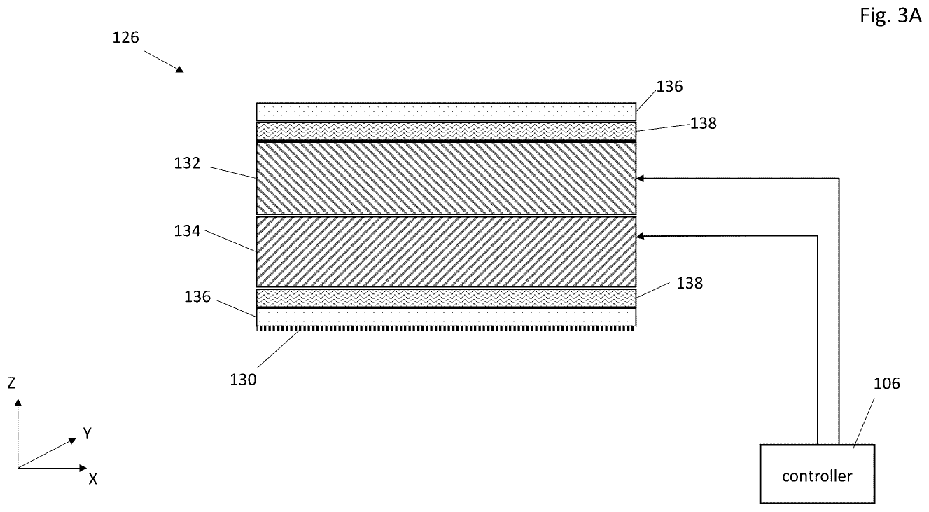

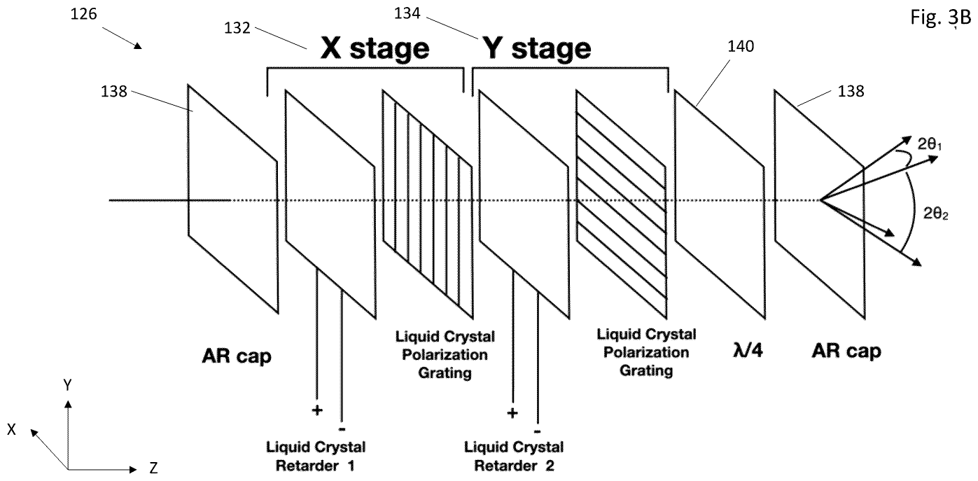

FIGS. 3A and 3B schematically show details of active diffraction grating 126, in accordance with an embodiment of the invention. FIG. 3A is a sectional view, while FIG. 3B is an exploded view showing functional elements of the active diffraction grating. Diffraction grating 126 comprises a variable 3D diffraction structure, which is implemented, for example, using two liquid crystal elements 132 and 134 with suitable electrodes to serve as an electro-optical spatial light modulator. Liquid crystal elements 132 and 134 are encapsulated in a transparent envelope 136, for example a glass envelope, which serves as the optical substrate of active diffraction grating 126. Additional layers 138 in active diffraction grating 126 may comprise, for example, polarization elements, optical filters, such as anti-reflection (AR) filters, and protective coatings.

Liquid crystal elements 132 and 134 are driven by controller 106 to provide a diffractive beam deflector with a tunable pitch and variable orientation. Specifically, in the present example, liquid crystal element 132 forms a grating along the Y-direction and thus deflects circularly polarized beams 112 along the X-direction, while liquid crystal element 134 forms a grating along the X-direction and thus deflects the circularly polarized beams 112 along the Y-direction. A liquid crystal retarder in each stage selects the direction of circular polarization (right or left), which determines the direction of deflection. Optionally, a quarter-wave plate 140 converts the output beam to linear polarization. Efficient liquid crystal gratings that may be used in this manner in active diffraction grating 126 are available, for example, from Meadowlark Optics (Frederick, Colorado).

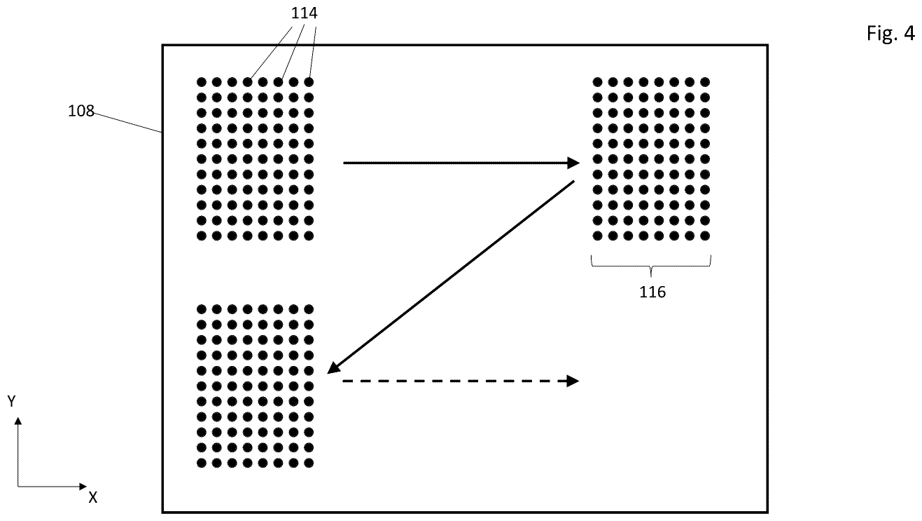

Liquid crystal elements 132 and 134 deflect beams 112 into the respective first diffraction orders of the diffraction gratings. By appropriate adjustment of the respective pitches of the two liquid crystal elements 132 and 134, active diffraction grating 126 will deflect beams over a range of elevation angles at any desired azimuth. The first diffraction orders of the projected beams can be scanned transversely in both the X- and Y-directions by varying the periods (i.e., the pitches) of the gratings by controller 106. A scan of this sort is shown, for example, in FIG. 4.

Optical metasurface 130 comprises an arrangement of sub-wavelength structures, for example pillars of varying diameters, which are formed on the surface of envelope 136. In one embodiment, the pillars comprise a semiconductor material, such as silicon (Si), which is etched from a silicon layer deposited on envelope 136. The pillars are embedded in a silicon dioxide (SiO₂) layer. Alternatively, the pillars may comprise a metallic material, etched from a suitable metal layer. Further alternatively, the pillars may be fabricated by other techniques, such as etching pillar-shaped holes in a SiO₂ layer, back-filling the holes with a desired pillar material, and then polishing the top of the SiO₂ layer.

To design metasurface 130 for a certain wavelength λ of VCSELs 122, the optical phase function Φ(x,y) (in radians) of the metasurface is computed from geometrical optics to find a set of coefficients Aₙ representing the quadratic phase components of the equivalent collimation lens:

$$Φ ( x , y ) = \frac{2 π}{λ} {\sum }_{n = 1}^{N} {{A}_{n} ( {x}^{2} + {y}^{2} )}^{n}$$

The computed value of the phase function at the location of each pillar on metasurface 130 is converted to a diameter of that pillar according to data provided by the metasurface manufacturer, and considering fabrication tolerances for dimensions such as the pillar sidewall angle and pillar height. A photolithographic mask for producing metasurface 130 with these pillar diameters is patterned according to these diameters, and metasurface is fabricated accordingly. Further details of this process are described, for example, in U.S. patent application Ser. No. 18/307,820, filed Apr. 27, 2023, which is assigned to the assignee of the present patent application and whose disclosure is incorporated herein by reference.

FIG. 4 is a schematic frontal view of target scene 108, illustrating the operation of active diffraction grating 126 in steering the pattern of spots 114 across the scene, in accordance with an embodiment of the invention. Controller 106 shifts the pattern across the scene in the X- and/or Y-directions by modification of the electrical signals applied to liquid crystal elements 132 and 134. Projection module 104 is thus able to create a high-resolution spot pattern in an area of interest within the scene, as well as scanning the pattern across multiple different parts of the scene.

The embodiments described above are cited by way of example, and the present invention is not limited to what has been particularly shown and described hereinabove. Rather, the scope of the present invention includes both combinations and subcombinations of the various features described hereinabove, as well as variations and modifications thereof which would occur to persons skilled in the art upon reading the foregoing description and which are not disclosed in the prior art.

1. Optoelectronic apparatus, comprising:
an array of emitters configured to emit respective beams of optical radiation;
a steering module, mounted to intercept the emitted beams and comprising:
an optical substrate;
an active diffraction grating, which is fixed to the optical substrate and has a pitch that varies in response to an electrical signal applied thereto, so as to deflect the beams of optical radiation by a variable angle dependent on the pitch; and
an optical metasurface disposed on the optical substrate and configured to collimate the beams of optical radiation so that the beams form a pattern of spots on a target scene; and
a controller coupled to vary the electrical signal applied to the active diffractive grating so as to shift the pattern of spots across the target scene.

2. The apparatus according to claim 1, wherein the emitters comprise vertical-cavity surface-emitting lasers (VCSELs).

3. The apparatus according to claim 1, wherein the active diffraction grating comprises an electro-optical material.

4. The apparatus according claim 3, wherein the electro-optical material comprises at least one liquid crystal.

5. The apparatus according to claim 4, wherein the at least one liquid crystal comprises a first liquid crystal, which is configured to deflect the beams of optical radiation along a first direction, and a second liquid crystal, which is configured to deflect the beams of optical radiation along a second direction, perpendicular to the first direction.

6. The apparatus according to claim 1, and comprising a receiver, which is configured to receive the optical radiation that is reflected from the pattern of spots on the target scene and to measure distances to points in the target scene responsively to the received optical radiation.

7. The apparatus according to claim 6, wherein the receiver has a field of view having a first angular width, while the pattern of spots extends over a second angular width, which is less than half the first angular width.

8. The apparatus according to claim 7, wherein the controller is configured to identify an area of interest within the field of view and to set the electrical signal so as to position the pattern of spots on the area of interest.

9. A method for optical projection, comprising:
directing an array of beams of optical radiation to impinge on a steering module, which comprises an active diffraction grating, which has a pitch that varies in response to an electrical signal applied thereto and is fixed to an optical substrate, and an optical metasurface disposed on the optical substrate and configured to collimate the beams of optical radiation so that the beams form a pattern of spots on a target scene; and
varying the electrical signal applied to the active diffractive grating so as to deflect the beams of optical radiation by a variable angle dependent on the pitch, thereby shifting the pattern of spots across the target scene.

10. The method according to claim 9, wherein the emitters comprise vertical-cavity surface-emitting lasers (VCSELs).

11. The method according to claim 9, wherein the active diffraction grating comprises an electro-optical material.

12. The method according claim 11, wherein the electro-optical material comprises at least one liquid crystal.

13. The method according to claim 12, wherein the at least one liquid crystal comprises a first liquid crystal, which is configured to deflect the beams of optical radiation along a first direction, and a second liquid crystal, which is configured to deflect the beams of optical radiation along a second direction, perpendicular to the first direction.

14. The method according to claim 9, and comprising receiving the optical radiation that is reflected from the pattern of spots on the target scene and measuring distances to points in the target scene responsively to the received optical radiation.

15. The method according to claim 14, wherein receiving the optical radiation comprises capturing the reflected optical radiation over a field of view having a first angular width, while the pattern of spots extends over a second angular width, which is less than half the first angular width.

16. The method according to claim 15, and comprising identifying an area of interest within the field of view, and setting the electrical signal so as to position the pattern of spots on the area of interest.
